(19) United States
(12) Patent Application Publication
(10) Pub. No.: US 2015/0301093 A1
(43) Pub. Date: Oct. 22, 2015

(54) FUNCTIONAL UNIT FOR MEASURING THE INSULATION RESISTANCE OF AN ELECTRICAL SYSTEM

(71) Applicant: Phoenix Contact GmbH & Co. KG, Blomberg (DE)

(72) Inventors: Heinz REIBKE, Bad Salzuflen (DE); Gerhard WOLFF, Extertal (DE)

(21) Appl. No.: 14/443,658

(22) PCT Filed: Nov. 19, 2013
(86) PCT No.: PCT/EP2013/074144

§ 371 Date: May 19, 2015

(30) Foreign Application Priority Data
Nov. 20, 2012 (DE) 10 2012 022 584.9

(51) Int. Cl. G01R 27/16; G01R 31/12

(52) U.S. Cl. CPC G01R 27/16; G01R 31/1227

(57) ABSTRACT

A functional unit measures the insulation resistance of an electrical system when the power supply of the electrical system is switched off. The electrical system includes an electrical reference potential, at least one electrical outer conductor, and an earth line. The functional unit is formed as a switch unit for connecting an electrical measurement device. The switch unit is configured to be connected to the electrical outer conductor, the electrical reference potential, and the earth line of the electrical system. The switch unit includes first, second, and third switches.

### CROSS-REFERENCE TO RELATED APPLICATIONS

This application is a U.S. National Phase Application under 35 U.S.C. §371 of International Application No. PCT/EP2013/074144, filed on Nov. 19, 2013, and claims benefit to German Patent Application No. DE 10 2012 022 584.9, filed on Nov. 20, 2012. The International Application was published in German on May 30, 2014 as WO 2014/079831 under PCT Article 21(2).

### FIELD

The invention relates to a functional unit for measuring the insulation resistance of an electrical system.

### BACKGROUND

A functional unit of this type is already known from DE 198 46 163 A1. The functional unit described therein is formed as an insulation testing device comprising an adapter, the adapter having at least one contact element for producing an electrically conductive connection of in each case one of the lines to be tested, namely the outer conductor, and comprising a neutral conductor contact for connection to a neutral conductor, namely the electrical reference potential of the known electrical system, and in that the contact element or elements and the neutral conductor contact in the adapter are electrically conductively interconnected.

### SUMMARY

In an embodiment, the present prevention provides a functional unit for measuring the insulation resistance of an electrical system when the power supply of the electrical system is switched off. The electrical system has an electrical reference potential, at least one electrical outer conductor, and an earth line. The functional unit comprises a switch unit for connecting an electrical measurement device. The switch unit is configured to be connected to the electrical outer conductor, the electrical reference potential, and the earth line of the electrical system. The switch unit comprises first, second, and third switches. The first switch in a closed position thereof electrically connects the electrical reference potential to the earth line. The second switch in a closed position thereof electrically connects the at least one electrical outer conductor to the electrical reference potential. The third switch in a closed position thereof mechanically releases an electrical port of a measurement port of the electrical measurement device for at least one of connection to the electrical reference potential or electrically connecting the electrical port to the electrical reference potential.

### BRIEF DESCRIPTION OF THE DRAWINGS

The present invention will be described in even greater detail below based on the exemplary figures. The invention is not limited to the exemplary embodiments. All features described and/or illustrated herein can be used alone or combined in different combinations in embodiments of the invention. The features and advantages of various embodiments of the present invention will become apparent by reading the following detailed description with reference to the attached drawings which illustrate the following:

FIG. 1 shows a first embodiment of a functional unit according to the invention.

FIG. 2 shows a second embodiment of a functional unit according to the invention.

FIG. 3 shows a third embodiment of a functional unit according to the invention.

FIG. 4 shows a fourth embodiment of a functional unit according to the invention.

FIG. 5 shows a fifth embodiment of a functional unit according to the invention.

FIG. 6 shows a sixth embodiment of a functional unit according to the invention.

FIG. 7 shows a seventh embodiment of a functional unit according to the invention.

### DETAILED DESCRIPTION

The functional unit according to an embodiment the invention is formed as a switch unit for connecting an electrical measurement device, and is itself connected to or formed so as to be connectable to the at least one electrical outer conductor, the electrical reference potential and the earth line of the electrical system, and comprises switches S1, S2 and S3, the switch S1 in the closed position thereof electrically connecting the reference potential to the earth line, the switch S2 in the closed position thereof electrically connecting the outer conductor to the reference potential, and the switch S3 in the closed position thereof mechanically releasing an electrical port for one of the measurement ports of the measurement device for connection to the reference potential and/or electrically connecting the electrical port to the reference potential. In this way, it is possible to measure the insulation resistance of the electrical system with fewer manual interventions by the metrologist than were previously necessary. Further, as a result operation is also possible from locations spatially remote from the electrical system. This also improves the operational reliability and reduces the risk of operating errors.

In principle, the formation and arrangement of the functional unit can be selected freely within wide suitable limits. An expedient development provides that the switches S1, S2 and S3 are constructionally integrated into the power supply of the electrical system at least in part. As a result of the constructional unification with components of the electrical system or coordinated systems indispensable therefor, such as the power supply of the electrical system, the functional unit is made compact in form.

A particularly advantageous development provides that the functional unit is formed as an adapter for retroactive mechanical and electrical connection to the electrical system. In this way, it is possible to equip even pre-existing electrical systems with a functional unit according to the invention retroactively in a simple manner, or to carry out insulation resistance measurements thereon. Further, the functional unit according to the invention can thus be used flexibly for different electrical systems, and this is particularly advantageous in mutually spatially separated electrical systems or the like.

In principle, the switch S3 can be selected freely within wide suitable limits as regards the type, operation and arrangement. A particularly advantageous development provides that the switch S3 itself is formed as a mechanical locking unit, which makes it possible to connect the measurement device when the switch S3 is in the closed position and prevents this when the switch S3 is in the open position.

A further advantageous development provides that the switches S1 and S2 and/or the switches S2 and S3 are mechanically, electromechanically or electronically coupled to one another. In this way, the desired switching sequence can be achieved in a particularly simple manner. The couplings between the individual switches S1, S2 and/or S2, S3 may also be mixed as regards the nature of the coupling, for example a mechanical coupling between the switches S1 and S2 and an electromechanical coupling between the switches S2 and S3.

Another advantageous development provides that a current sensor for measuring the flow of current in the earth line is additionally integrated into the functional unit. This makes continuous current measurement possible without additional apparatus. In this way, worsening of the insulation resistance becomes apparent the moment it occurs.

An advantageous development of the aforementioned embodiment provides that means for amplifying and preparing the output signal of the current sensor are integrated into the functional unit. In this way, a further constructional consolidation and thus a more compact construction are achieved. Meanwhile, the subsequent signal transmission and processing are improved as a result.

A further advantageous development provides that illuminated displays L1 and L2 are integrated into the functional unit, it being possible for the illuminated display L1 to switch on as a function of the operating state of the power supply of the electrical system and the position of the switch S1 and for the illuminated display L2 to switch on as a function of the operating state of the power supply of the electrical system and the position of the switch S2. As a result, it is possible to monitor the functional unit in a particularly simple manner. In addition or alternatively, other signalling means known to the person skilled in the art are also conceivable, for example acoustic signalling means such as buzzers or the like.

In principle, the use of the functional unit can be selected freely within wide suitable limits as regards the type of electrical system. Electrical terminals, in particular serial terminals, are a particularly significant field of use for the functional unit. Expediently, as well as the electrical port for one of the measurement ports of the measurement device, the adapter therefore comprises further electrical ports, which are suitable for and configured for being contacted with electrical terminals, in particular serial terminals.

Further, the actuation of the individual switches S1, S2 and S3 can be selected freely within wide suitable limits as regards the type and operation. An advantageous development provides that the switch unit comprises a handle by means of which the switches S1, S2 and S3 can be actuated jointly, for example synchronously. In this way, joint actuation of the switches S1, S2 and S3 is possible by a single manual actuation and thus in a particularly simple manner. In this context, the use of a rotary handle is particularly advantageous, since this improves for example the comfort of operation by comparison with linearly movable handles.

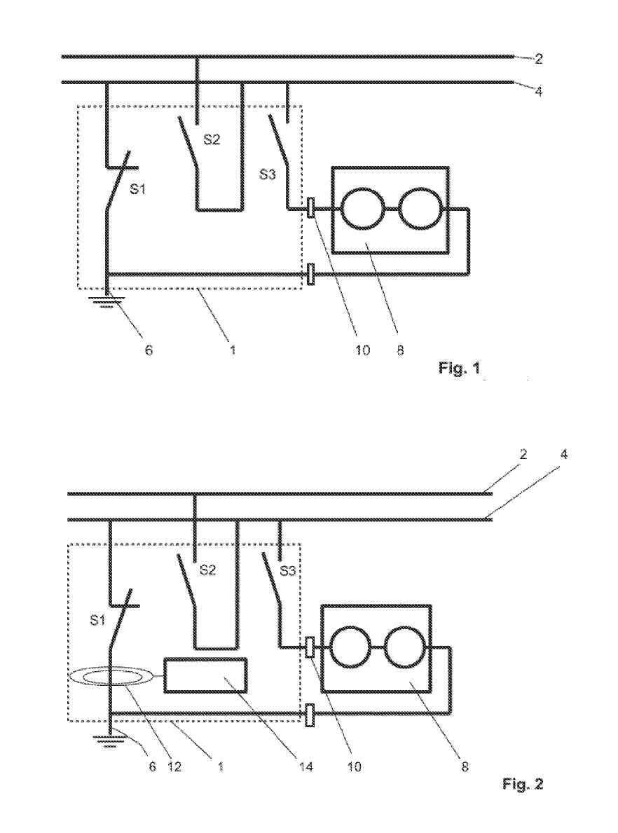

FIG. 1 shows a first embodiment of the functional unit according to the invention. The functional unit is formed as a switch unit 1 and is bordered by a dashed line in FIG. 1. In the plane of the page, above the switch unit 1, an electrical outer conductor 2, an electrical reference potential 4 and an earth line 6 of an electrical system are shown, as well as the power supply of the electrical system. In the following, the outer conductor 2, reference potential 4 and earth line 6 are jointly referred to as electrical conductors 2, 4 and 6. The switch unit 1 is formed as an integral component of the electrical circuit of the electrical system. In the present embodiment, electrical stubs branch off from the electrical conductors 2, 4 and 6 into the switch unit 1, and are thus electrically conductively connected to the switches S1, S2 and S3. As can clearly be seen from FIG. 1, the switch S1 in the closed position thereof connects the reference potential 4 to the earth line 6, the switch S2 in the closed position thereof connects the outer conductor 2 to the reference potential 4, and the switch S3 in the closed position thereof connects an electrical port 10 for one of the two measurement ports, for example the plus pole, of an electrical measurement device 8 for measuring the insulation resistance of the electrical system to the reference potential 4.

During the insulation measurement, testing is usually carried out using a DC voltage. The potential level may be as desired. Therefore, either the plus or the minus pole may be present at the electrical port 10. To simplify any further explanations, only the plus pole of the electrical measurement device 8 is discussed in the following. However, it is clear from the above that this in no way limits the invention. According to the invention, both the plus and the minus pole of the electrical measurement device 8 may be electrically conductively connected to the electrical port 10.

The switches S1, S2 and S3 are formed as electromechanical switches, the switch SI being formed as an N/C switch and the switches S2 and S3 being formed as N/O switches, meaning that FIG. 1 shows the switches S1, S2 and S3 in the respective idle states thereof. It is possible to actuate each of the switches S1, S2 and S3 individually, but for reasons of operational reliability and thus of error-free operation, as well as of comfort of operation, it is provided that the switches S1, S2 and S3 are formed as a combination switch which constructionally unites all three switches S1, S2 and S3. The combination switch comprises a rotary handle for manual actuation by an operator. The switches S1, S2 and S3 are therefore mechanically coupled to one another in such a way that by a single manual actuation action, for example by rotating the handle of the combination switch clockwise, initially the switch S2 is brought from the open position thereof into the closed position and subsequently the switch S3 is brought from the open position thereof into the closed position and finally the switch S1 is brought from the closed position into the open position thereof.

Further, in the present embodiment it is provided that the electrical port 10 on the switch unit 1 for the connection of the plus pole of the measurement device 8 additionally comprises a mechanical locking unit for the electrical port 10, which makes it possible to electrically contact the plus pole of the measurement device 8 with the electrical port 10 of the switch unit 1 when the switch S3 is in the closed position and mechanically blocks the electrical port 10 for the connection of the plus pole of the measurement device 8 when the switch S3 is in the open position, in other words prevents the electrical contact.

In this way, double protection is provided against undesired electrical connection of the plus pole of the measurement device 8 to the electrical reference potential 4 of the electrical system, specifically on the one hand the opening of the electrical connection by the switch S3 and on the other hand the mechanical blocking of the electrical port 10. In the present embodiment, the switch S3 and the mechanical locking unit are coupled together for this purpose in a manner known to the person skilled in the art. In principle, however, it is also possible for the switch S3 and the mechanical locking unit to be manually, electromechanically or electronically actuable independently of one another.

To measure the insulation resistance of the electrical system, it is therefore merely necessary initially to switch off the power supply of the electrical system and subsequently to rotate the handle of the combination switch clockwise into the end position thereof, in such a way that the switching states, described in detail above, of the switches S1, S2 and S3 are adopted in the disclosed temporal sequence. Since in this way the electrical port 10 of the switch unit 1 has also been mechanically released, the measurement device 8 can subsequently be connected by the plus pole to the electrical port 10 of the switch unit 1 and the insulation resistance can be measured in a manner known per se.

In bipolar power supply systems, the switch S2 should preferably be configured in such a way that the positive pole and the negative pole are short-circuited with the reference potential simultaneously.

If there are more than two outer conductors, these are likewise preferably short-circuited with the reference potential simultaneously. Accordingly, all of the outer conductors are initially electrically conductively connected to the reference potential before the switch S3 is closed and the switch S1 is opened.

If it is found during the measurement that the measurement value is above the system-specific minimum value for the insulation resistance, the measurement is terminated, in other words the electrical contact of the plus pole of the measurement device 8 with the electrical port 10 is opened again and the switch unit 1 is brought back into the idle state of FIG. 1, in such a way that the operation of the electrical system can be taken up again.

This takes place as follows:

In the opposite actuation direction of the handle of the aforementioned combination switch from during the rotation thereof anticlockwise into the other end position, initially the switch S1 is brought from the open position thereof into the closed position thereof and subsequently the switch S3 is brought from the closed position thereof into the open position thereof, causing the electrical port 10 to be blocked by the mechanical locking unit and the electrical connection between the reference potential 4 and the electrical port 10 simultaneously to be opened. Finally, the switch S2 is brought from the closed position thereof into the open position thereof.

The power supply of the electrical system can now be switched back on again, so as to continue the normal operation of the electrical system.

The mechanical locking of the electrical port 10 ensures in a simple and robust manner that no test voltage can be applied to the electrical system. This effectively prevents damage such as could for example have occurred in the previously conventional procedure.

However, if the measurement shows that the measurement value is below the system-specific minimum value, the error in the electrical system initially has to be searched for and eliminated, before the system can be released for operation again after further measurement of the insulation resistance with a measurement result which in this case meets the requirements on the electrical system.

In principle, however, it is also possible for the switches S2 and S3 to be actuated simultaneously. In this case, it is possible for example to move one function of the switch S3 of the first embodiment—specifically bringing the mechanical locking unit for the electrical port 10 into the blocking position or open position thereof as a function of the switch position of the switch S3—by way of the switch S2 and thus as a function of the switch position thereof. If for other applications it is possible and expedient to dispense with the aforementioned double protection, in this case the switch S3 may merely be formed as a mechanical locking unit.

The switch unit 1 is completely integrated into the power supply of the electrical system; however, a merely partial constructional integration is also conceivable in principle.

The handle of the aforementioned combination switch may also be formed in such a way that it can only be actuated using a special tool, for example a screwdriver, so as effectively to prevent undesired actuation.

It is further possible for the combination switch, or alternatively each of the individual switches S1, S2 and S3, to be electrically, electromechanically or electronically actuable or to be formed as an electrical, electromechanical or electronic switch. For this purpose, means are known to the person skilled in the art for carrying out an actuation of this type in the desired switching sequence; the same applies to the mechanical locking of the electrical port 10 as a function of or independent of the switch position of switch S3, switch S2.

The further embodiments of the functional unit according to the invention are merely described in terms of the differences from the first embodiment. In other respects, the further embodiments correspond to the first embodiment, and so reference is made to the above statements in this regard. Like or corresponding components have like reference numerals.

FIG. 2 shows a second embodiment of the functional unit according to the invention, formed as a switch unit 1. Unlike the first embodiment, this embodiment additionally comprises a current sensor 12 formed as a Hall sensor, which is used for measuring the flow of current in the earth line 6, means or devices 14 for amplifying and preparing the output signal of the current sensor 12 being integrated into the switch unit 1. The further signal preparation and processing can subsequently also take place for example in a superordinate evaluation unit. The measures required for this purpose are sufficiently well-known to the person skilled in the art. For reasons of operational reliability, the power supply of the current sensor 12 and of the means/devices 14 may be provided by a power supply independent from the electrical system. In this way, a flow of any type of current through the earth line 6 can be detected even when the electrical system is switched off.

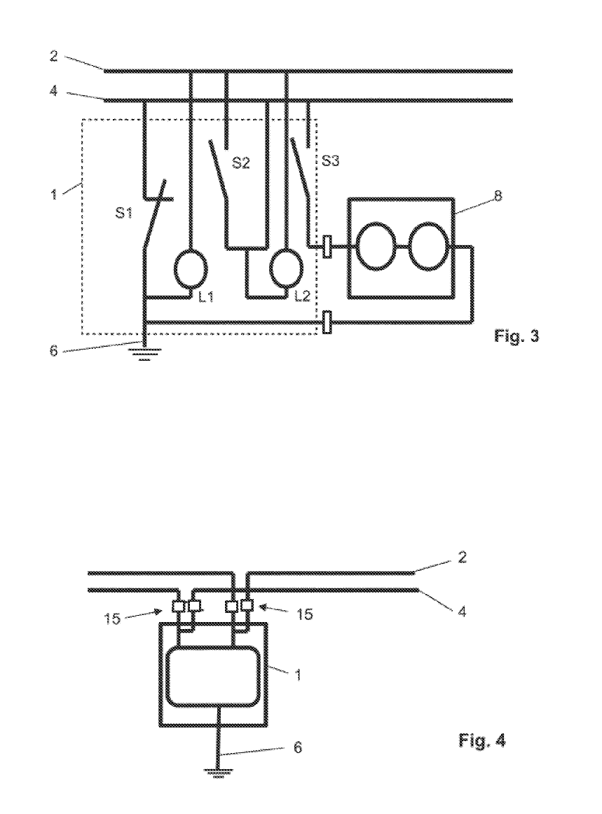

FIG. 3 shows a third embodiment, in which illuminated displays L1 and L2 are integrated into the switch unit 1, it being possible for the illuminated display L1 to switch on as a function of the operating state of the power supply of the electrical system and the position of the switch S1, and for the illuminated display L2 to switch on as a function of the operating state of the power supply of the electrical system and the position of the switch S2.

In this embodiment, if the electrical system has no earth connection, the illuminated display L1 lights up when the power supply is switched on and the switch S1 is closed, whilst the illuminated display L2 lights up when the power supply is switched on and the switch S2 is open.

If L1 and L2 are lit up, the electrical system is in normal operation. If only L2 is lit up, the power supply is switched on but switch S1 is not closed. If neither L1 nor L2 is lit up, the power supply is switched off or the switch S2 is closed.

As already explained above, it is possible to connect the switch unit 1 electrically conductively to the electrical system via what are known as stub ports.

In principle, however, it is also possible to provide the electrical connection of the switch unit 1 to the outer conductor 2, the electrical reference potential 4 and the earth line 6 of the electrical system by way of what is known as feed-through wiring. For this purpose, in a fourth embodiment at least two interconnected electrical connection points 15, for example terminal points, are required for each of the electrical conductors 2 and 4; see FIG. 4.

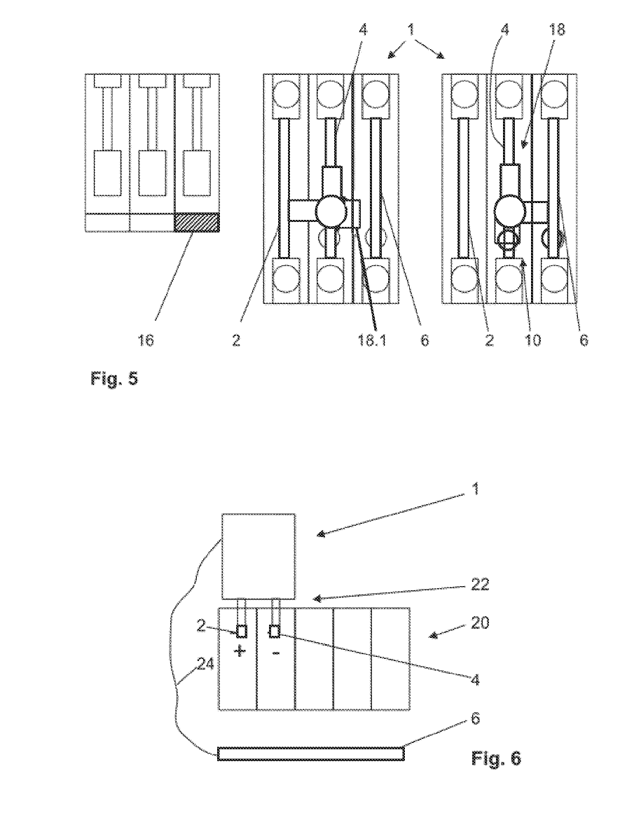

As is shown in FIG. 5 by way of example, a fifth embodiment provides that the switch unit 1 is configured as an adapter formed as a terminal block, in such a way that the switch unit 1 can be plugged onto a support rail 16, for example formed as a top-hat rail, or the like. The switch unit 1 thus provided is connected to the electrical earth potential via the support rail 16. The combination switch known from the first embodiment is likewise formed as an electromechanical combination switch 18 in this case. As is shown symbolically in FIG. 5, the combination switch 18 establishes, depending on the switch position thereof, an electrically conductive connection between the outer conductor 2 and the reference potential 4 and between the reference potential 4 and the earth line 6, the combination switch 18 also comprising a mechanical locking unit 18.1.

The situation where the electrical system is operating is shown in the drawing, on the far right in the plane of the page, of the switch unit 1 formed as a terminal block. The switch position of the combination switch 18 corresponds to that of the switch S1 in the closed position thereof and to that of the switches S2 and S3 in the open positions thereof, in such a way that the reference potential 4 is connected to the electrical earth potential via the earth line 6 and the support rail 16 and the mechanical locking unit 18.1 blocks the electrical port 10, in such a way that the plus pole of the measurement device cannot be connected to the switch unit 1.

By contrast, the drawing of the switch unit 1 formed as a terminal block in the centre of the plane of the page shows the measurement situation. The switching position of the combination switch 18 corresponds to that of the switch S1 in the open position thereof and to that of the switches S2 and S3 in the closed positions thereof, in such a way that the outer conductor 2 is connected to the reference potential 4 and the mechanical locking unit 18.1 has released the electrical port 10, in such a way that the plus pole of the measurement device can be connected to the switch unit 1. The drawing on the far left in the plane of the page is a schematic side view of the switch unit 1 formed as a terminal block.

In this embodiment, the switch S3 implemented in the combination switch 18 is itself formed as a mechanical locking unit 18.1. There is no separation between the switch S3 and the mechanical locking unit 18.1. Accordingly, in this case the closed position of the switch S3 means the position of the mechanical locking unit 18.1 which makes electrical contact of the plus pole of the measurement device with the electrical port 10 possible. According to the invention, the switch S3 is a switch in the broad sense. The switch S3 may be a mechanical, electrical, electromechanical or electronic switch, which establishes or breaks an electrical connection in the conventional meaning depending on the switch position. As described above, however, this need not be the case. Any type of combination is possible, as is the omission of an additional protection in the form of a mechanical locking unit.

The switch unit 1 may be formed as a plug-on unit in accordance with FIG. 6, so as to be plugged onto electrical terminals, in particular serial terminals 20, so as to establish a releasable mechanical and electrical connection between the switch unit 1 and the electrical terminal 20 in a manner known per se. For this purpose, as well as the electrical port 10, the sixth embodiment shown in FIG. 6 comprises further electrical ports 22, which are suitable for and formed for being connected to electrical terminals 20, in particular serial terminals, for example via plug connections known per se, specifically to the outer conductor 2 and the electrical reference potential 4 of the electrical terminal 20. In the present embodiment, the switch unit 1 is electrically connected to the earth line 6 via a flexible line 24. Alternatively, a type of plug connection analogous to the further electrical ports 22 would naturally also be conceivable.

In a combination of the fifth and sixth embodiment, a terminal block formed as a plug-on unit is also conceivable as an implementation of a switch unit 1.

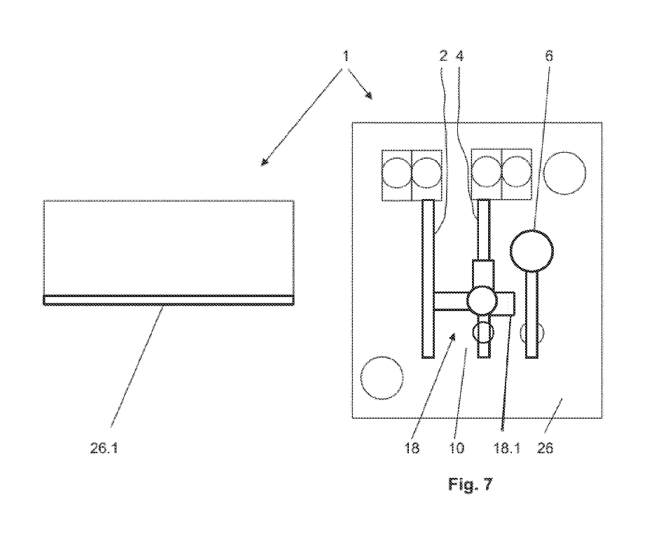

Further, a seventh embodiment in accordance with FIG. 7 shows the switch unit 1 formed suitable for mounting on a plate 26. The switch unit 1 is for example fixed to the plate 26 by a screw connection, the plate 26 comprising an electrically conductive base layer 26.1 for connection to the earth, as can be seen from the side view on the left in the plane of the page. The drawing on the right is a schematic plan view.

As is also the case in the other embodiments, the electrically conductive connection to the earth may be provided via terminals or double terminals or else by means of a flexible line.

Analogously to the fifth embodiment, an electromechanical combination switch 18 is used in this case too, and so reference may be made to the above statements in this regard.

The invention is not limited to the aforementioned embodiments. In particular, combinations of individual aspects from the embodiments are possible depending on the application. The switches S1, S2 and S3 may each be configured as separate switches or else in any desired combinations. The same applies to the functional principles for the switches S1, S2 and S3. Combination of the switches is not merely limited to constructional unification of individual switches to form a module or a combination switch, which thus takes on the functions of a plurality of switches out of the switches S1, S2 and S3. Rather, the actual selection of the respective combination is determined by the type, scope and functional and spatial connection of the individual switches S1, S2 and S3 in accordance with the use scenario. This applies in particular to the formation of the switch S3 and/or of the mechanical locking unit. Both the use merely of a switch S3 for electrically opening/closing an electrical circuit and the use merely of a mechanical device are conceivable, as well as the combination of the two.

The above statements further apply to all voltage types, voltage polarities and voltage levels, including low-voltage, as well as to power supplies having more than two potentials.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE NUMERALS

switch unit 1

outer conductor 2

electrical reference potential 4

earth line 6

measurement device 8

electrical port for one of the measurement ports, for example the plus pole, of the measurement device 10

current sensor 12

amplification and preparation devices 14

electrical connection point 15

support rail 16

electromechanical combination switch 18

mechanical locking unit 18.1

electrical terminal, in particular serial terminal 20

further electrical ports 22

flexible line 24

plate 26

electrically conductive base layer 26.1

1. A functional unit for measuring the insulation resistance of an electrical system when a power supply of the electrical system is switched off, the electrical system having an electrical reference potential at least one electrical outer conductor and an earth line, the functional unit comprising:
a switch unit for connecting an electrical measurement device, the switch unit being configured to be connected to the electrical outer conductor, the electrical reference potential, and the earth line of the electrical system, the switch unit comprising first, second, and third switches, the first switch, in a closed position thereof electrically connecting the electrical reference potential to the earth line, the second switch, in a closed position thereof, electrically connecting the at least one electrical outer conductor to the electrical reference potential, and the third switch, in a closed position thereof, mechanically releasing an electrical port of a measurement port of the electrical measurement device for at least one of connection to the electrical reference potential or electrically connecting the electrical port to the electrical reference potential.

2. The functional unit according to claim 1, wherein the first, second, and third switches are constructionally integrated into a power supply of the electrical system at least in part.

3. The functional unit according to claim 1, wherein the switch unit is formed as an adapter for retroactive mechanical and electrical connection to the electrical system.

4. The functional unit according to claim 1, wherein the third switch is formed as a mechanical locking unit that as configured, in the closed position, to connect the electrical measurement device and, in an open position, to prevent disconnection of the electrical measurement device.

5. The functional unit according to claim 1, wherein at least one of the first and second switches and the second and third switches are mechanically, electromechanically, or electronically coupled to one another.

6. The functional unit according to claim 1, further comprising a current sensor configured to measure a flow of current in the earth line, the current sensor being integrated into the functional unit.

7. The functional unit according to claim 6, further comprising a device configured to amplify and prepare an output signal of the current sensor, the device being integrated into the functional unit.

8. The functional unit according to claim 1, further comprising first and second illuminated displays integrated into the functional unit, the first illuminated display being configured to switch on as a function of an operating state of a power supply of the electrical system and a position of the first switch, and the second illuminated display being configured to switch on as a function of the operating state of the power supply of the electrical system and a position of the second switch.

9. The functional unit, according to claim 3, wherein the adapter comprises electrical ports configured to be connected to one or more electrical terminals, in particular serial terminals.

10. The functional unit according to claim 1, wherein the switch unit comprises a handle configured to jointly actuate the first, second, and third switches.
